(19) United States
(12) Patent Application Publication
(10) Pub. No.: US 2010/0044881 A1
(43) Pub. Date: Feb. 25, 2010

(54) SEMICONDUCTOR DEVICE AND FABRICATION METHOD THEREOF

(76) Inventor: Hiroaki Fujimoto, Osaka (JP)

Correspondence Address: MCDERMOTT WILL & EMERY LLP, 600 13TH STREET, NW, WASHINGTON, DC, 20005-3096, US

(21) Appl. No.: 12/483,651

(22) Filed: Jun. 12, 2009

(30) Foreign Application Priority Data
Aug. 21, 2008 (JP) 2008-212825

(51) Int. Cl. H01L 23/52; H01L 21/00

(52) U.S. Cl. 257/777; 438/109; 257/E21.002; 257/E23.142

(57) ABSTRACT

A semiconductor device includes: a first semiconductor element; a second semiconductor element mounted on an upper surface of the first semiconductor element via an adhesive layer; a mold resin body for overmolding the first semiconductor element and the second semiconductor element; and a first spherical filler having a diameter smaller than an average thickness of the adhesive layer and a second spherical filler having a diameter larger than the average thickness of the adhesive layer, the first or second spherical filler being dispersed in the mold resin body. The mold resin body does not contain a spherical filler which has a diameter substantially equal to the average thickness of the adhesive layer.

### CROSS-REFERENCE TO RELATED APPLICATIONS

This application claims priority from Japanese Patent Application JP2008-212825 filed on Aug. 21, 2008, the disclosure of which application is hereby incorporated by reference into this application in its entirety for all purposes.

### BACKGROUND

The techniques disclosed in this specification are directed to a semiconductor device in which semiconductor elements are overmolded with a mold resin and to a fabrication method of the semiconductor device.

A conventional resin-overmolded semiconductor device includes, for example, a first semiconductor element in the form of a chip, a second semiconductor element in the form of a chip adhered onto the upper surface of the first semiconductor element via a die-bond sheet, a mold resin body overmolding the first and second semiconductor elements, and a lead electrically connected to at least one of the first and second semiconductor elements inside the mold resin body, at least part of the lead extending out of the mold resin body.

The mold resin body is formed by injecting a thermosetting resin which contains spherical fillers into a metal mold. Here, the diameter of the spherical fillers is smaller than the distance between the first semiconductor element and the second semiconductor element, so that the first and second semiconductor elements are not susceptible to damage (see, for example, Japanese Laid-Open Patent Publication No. 2008-53505).

Thus, due to such a feature of the conventional semiconductor device that the diameter of the spherical fillers contained in the mold resin body is smaller than the distance between the first semiconductor element and the second semiconductor element, the first and second semiconductor elements are not susceptible to damage even when pressure from the mold resin body is exerted on the part between the first semiconductor element and the second semiconductor element in which the spherical fillers are sandwiched.

### SUMMARY

As described above, the smaller diameter of the spherical fillers serves to prevent the stacked first and second semiconductor elements from being damaged by the spherical fillers biting into the gap between the first and second semiconductor elements. However, in this case, the thermosetting resin containing the spherical fillers has a very high viscosity and, as a result, does not smoothly flow inside the metal mold, which can be a cause of molding failure.

A semiconductor device and a fabrication method thereof which are disclosed in this specification can prevent the first and second semiconductor elements from being damaged by the spherical fillers biting into the gap between the first and second semiconductor elements and can prevent molding failure.

An example semiconductor device of the present invention includes a first semiconductor element, a second semiconductor element mounted on an upper surface of the first semiconductor element via an adhesive layer, a mold resin body overmolding the first semiconductor element and the second semiconductor element, and a first spherical filler dispersed in the mold resin body which has a diameter smaller than an average thickness of the adhesive layer or a second spherical filler dispersed in the mold resin body which has a diameter larger than the average thickness of the adhesive layer.

Due to this structure, even when the first spherical filler enters the space between the first semiconductor element and the second semiconductor element during the resin injection step, the first and second semiconductor elements are not susceptible to damage by the first spherical filler because the diameter of the first spherical filler is small. The second spherical filler has a larger diameter and therefore does not enter the space between the first semiconductor element and the second semiconductor element. Thus, the second spherical filler does not damage the first semiconductor element or the second semiconductor element. Further, the resin exhibits improved flowability during the resin injection step because the second spherical filler having a larger diameter is contained therein. Accordingly, occurrence of molding failure is prevented.

Preferably, the mold resin body does not contain a spherical filler which has a diameter substantially equal to the average thickness of the adhesive layer.

An example semiconductor device fabrication method of the present invention includes: (a) mounting a second semiconductor element on an upper surface of a first semiconductor element via an adhesive layer; and (b) after (a), injecting a thermosetting resin into a metal mold holding the first semiconductor element and the second semiconductor element placed therein to form a mold resin body that overmolds the first and second semiconductor elements, wherein the thermosetting resin used in (b) contains a first spherical filler which has a diameter smaller than an average thickness of the adhesive layer and a second spherical filler which has a diameter larger than the average thickness of the adhesive layer.

With this method, even when the first spherical filler enters the space between the first semiconductor element and the second semiconductor element in step (b), the first spherical filler does not bite into the gap between the first semiconductor element and the second semiconductor element. The second spherical filler does not enter the space between the first semiconductor element and the second semiconductor element. Thus, the first and second semiconductor elements are not susceptible to damage. Further, the second spherical filler contained in the resin improves the flowability of the resin, and therefore, molding failure of the mold resin body is prevented.

### BRIEF DESCRIPTION OF THE DRAWINGS

FIG. 1 is a perspective view showing an exterior of an example semiconductor device of an embodiment.

FIG. 2 is a cross-sectional view of the example semiconductor device taken along line II-II of FIG. 1.

FIG. 3 is an enlarged vertical cross-sectional view of the example semiconductor device, showing the details of encircled portion A of FIG. 2.

FIG. 4 is an enlarged view of the example semiconductor device, showing the details of encircled portion A of FIG. 2 when seen from the top.

FIG. 5 is a plan view illustrating a mold resin body formation step of a fabrication process of the example semiconductor device.

FIG. 6 is a partially-enlarged, cross-sectional view of a comparative semiconductor device example.

FIG. 7 shows the grain size distribution of the spherical fillers contained in a mold resin body of the example semiconductor device.

FIGS. 8A and 8B are enlarged cross-sectional views for illustrating the advantages of the example semiconductor device.

FIG. 9 is a cross-sectional view of a specific example semiconductor device which is different from the example semiconductor device of FIG. 1.

FIG. 10 is a cross-sectional view of another specific example semiconductor device.

FIG. 11 is a cross-sectional view of still another specific example semiconductor device.

FIG. 12A is an enlarged cross-sectional view partially showing a specific example semiconductor device. FIG. 12B is an enlarged cross-sectional view partially showing another specific example semiconductor device.

### DETAILED DESCRIPTION

Hereinafter, an example semiconductor device of an embodiment is described with reference to the drawings.

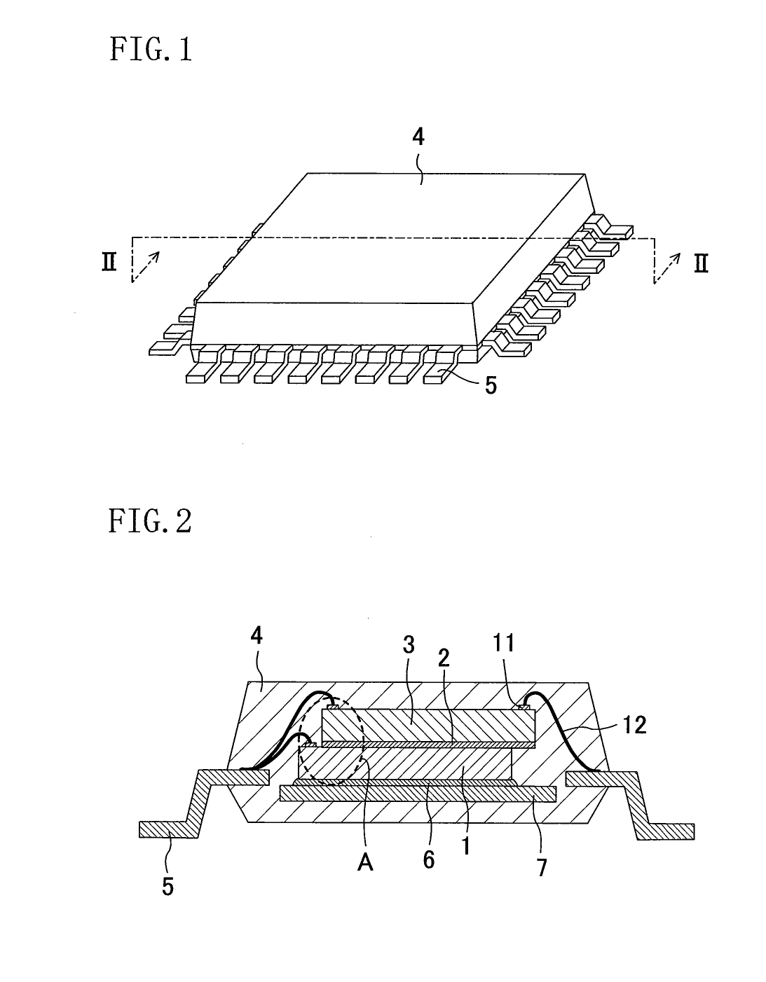

FIG. 1 is a perspective view showing an exterior of the example semiconductor device. FIG. 2 is a cross-sectional view of the example semiconductor device taken along line II-II of FIG. 1.

Referring to FIG. 1 and FIG. 2, the example semiconductor device of the present embodiment includes a die pad (element supporter) 7, a first semiconductor element 1 in the form of a chip mounted on the die pad 7 via a die bond agent 6, a second semiconductor element 3 adhesively mounted on the upper surface (circuit-formed surface) of the first semiconductor element 1 via a die bond sheet (adhesive layer) 2, a plurality of leads 5 provided around the perimeter of the die pad 7 and electrically connected to at least one of the first semiconductor element 1 and the second semiconductor element 3, metal wires (connectors) 12 connecting the respective one of the plurality of leads 5 to the first semiconductor element 1 or the second semiconductor element 3, and a mold resin body 4 overmolding the first semiconductor element 1, the second semiconductor element 3, part of the plurality of leads 5, and the metal wires 12. Part of each lead 5 which is connected to the metal wire 12 is overmolded by the mold resin body 4, while the other part of the lead 5 protruding out of the mold resin body 4 serves as an external terminal. The mold resin body 4 has, for example, a four-sided shape when seen from the top. The plurality of leads 5 are outwardly protruding at the four sides of the mold resin body 4.

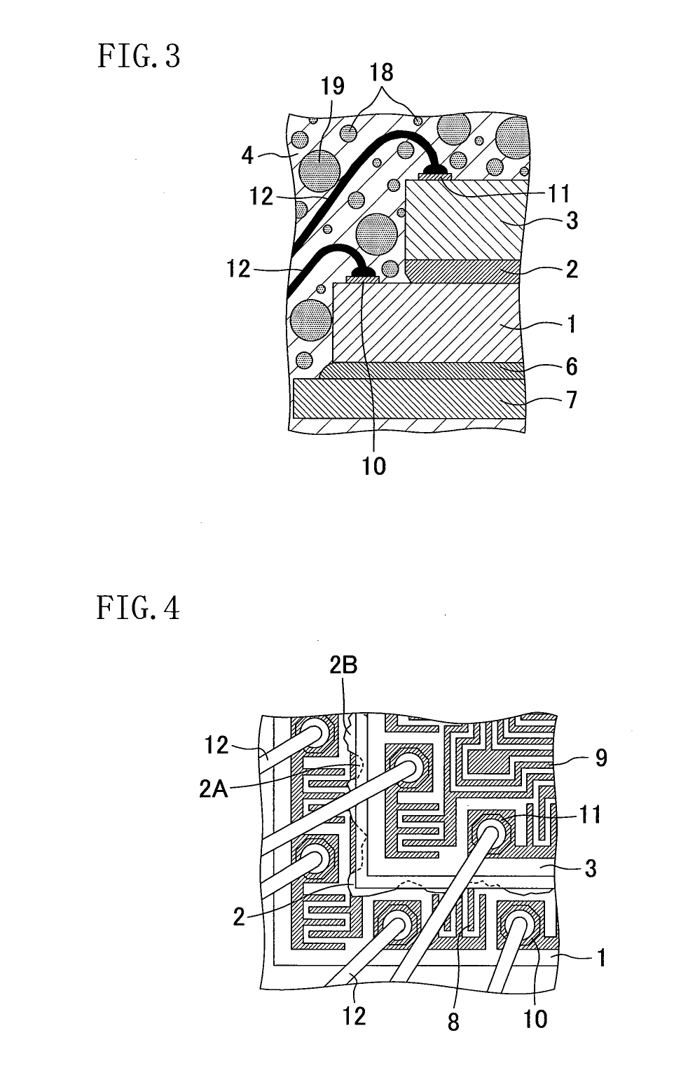

FIG. 3 is an enlarged vertical cross-sectional view of the example semiconductor device, showing the details of encircled portion A of FIG. 2. FIG. 4 is an enlarged view of the example semiconductor device, showing the details of encircled portion A of FIG. 2 when seen from the top.

Referring to FIG. 3 and FIG. 4, the first semiconductor element 1 has, on its upper surface, wires 8 and electrodes 10 connected to the wires 8. The second semiconductor element 3 has, on its upper surface, wires 9 and electrodes 11 connected to the wires 9. The metal wires 12 are connected to the electrodes 10 or to the electrodes 11. The die bond sheet 2 is made of a thermosetting resin and has a thickness of, for example, about 1 to 100 μm.

In the example semiconductor device of the present embodiment as shown in FIG. 3, the mold resin body 4 contains first spherical fillers 18 which have smaller diameters than the thickness of the die bond sheet 2 and second spherical fillers 19 which have larger diameters than the thickness of the die bond sheet 2, the spherical fillers 18 and 19 being dispersed throughout the mold resin body 4. As will be described later, this feature serves to prevent the first semiconductor element 1 and the second semiconductor element 3 from being damaged by the spherical fillers and to improve the flowability of the resin material during formation of the mold resin body 4 so that occurrence of molding failure can be prevented.

Next, a fabrication method of the example semiconductor device is described.

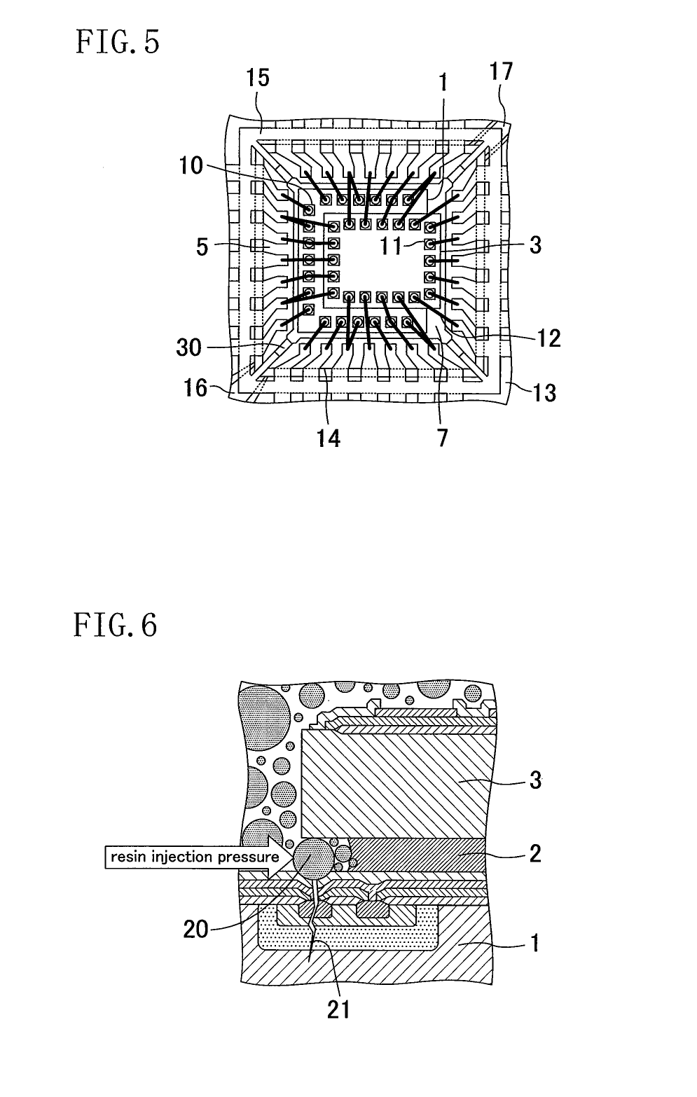

FIG. 5 is a plan view illustrating the step of forming the mold resin body 4 in an example semiconductor device fabrication process. FIG. 5 shows a state where an integrated device piece (semiconductor device in fabrication) is placed in a cavity 14 of a metal mold 13. Here, the integrated device piece is an element in which the die bond agent 6, the first semiconductor element 1, the die bond sheet 2 and the second semiconductor element 3 have been sequentially formed over the die pad 7, and the electrodes 10 and 11 and the leads 5 have been electrically coupled by metal wires 12.

In fabrication of the example semiconductor device of the present embodiment, a leadframe 15 is first prepared which includes the plurality of leads 5, the die pad 7, and suspending leads 30 for supporting the die pad 7. The first semiconductor element 1 is then adhered onto the upper surface of the die pad 7 via the die bond agent 6. Then, the second semiconductor element 3 is adhered onto the upper surface of the first semiconductor element 1 via the die bond sheet 2. In this step, the second semiconductor element 3 is mounted such that the electrodes 10 are exposed. Note that the die bond sheet 2 is fixed to the lower surface of the second semiconductor element 3 in advance before the second semiconductor element 3 is adhered onto the first semiconductor element 1. Specifically, a large-surface die bond sheet member is adhered over the lower surface of the wafer of the plurality of second semiconductor elements 3. Then, the second semiconductor elements 3 with the die bond sheet 2 adhered over the lower surface are isolated by dicing that approaches from the upper surface side. In this step, the die bond sheet 2 is sometimes caught by a dicing blade, so that the second semiconductor elements 3 are isolated with the die bond sheet 2 torn apart. As a result, the horizontal profile of the die bond sheet 2 has such a shape that recesses and protrusions irregularly occur relative to the horizontal profile of the second semiconductor element 3.

Then, the electrodes 10 and 11 and the leads 5 are coupled by the metal wires 12, and the resultant semiconductor device in fabrication is placed in the metal mold 13 as shown in FIG. 5. Note that the metal mold 13 is formed by the upper and lower parts, but the metal mold 13 in FIG. 5 is schematically shown for avoiding complexity. The leads 5 are protruding out of the metal mold 13, and are sandwiched by the upper and lower parts of the metal mold 13. Then, in such a state, a thermosetting resin (for example, epoxy resin) is injected into the cavity 14 via a gate 16 of the metal mold 13 heated to about 180° C. while pressure is applied to the resin. In this step, the injected thermosetting resin flows inside the cavity 14 toward an air vent 17 positioned diagonally opposite to the gate 16, and thereafter, setting of the resin gradually advances from the air vent 17 side toward the gate 16. After complete setting of the thermosetting resin, the metal mold 13 is removed, and the leads 5 are cut away from the frame rim of the leadframe 15. Thus, the example semiconductor device covered with the mold resin body 4 as shown in FIG. 1 and FIG. 2 is completed.

The above example semiconductor device of the present embodiment is now described in more details with reference to the drawings.

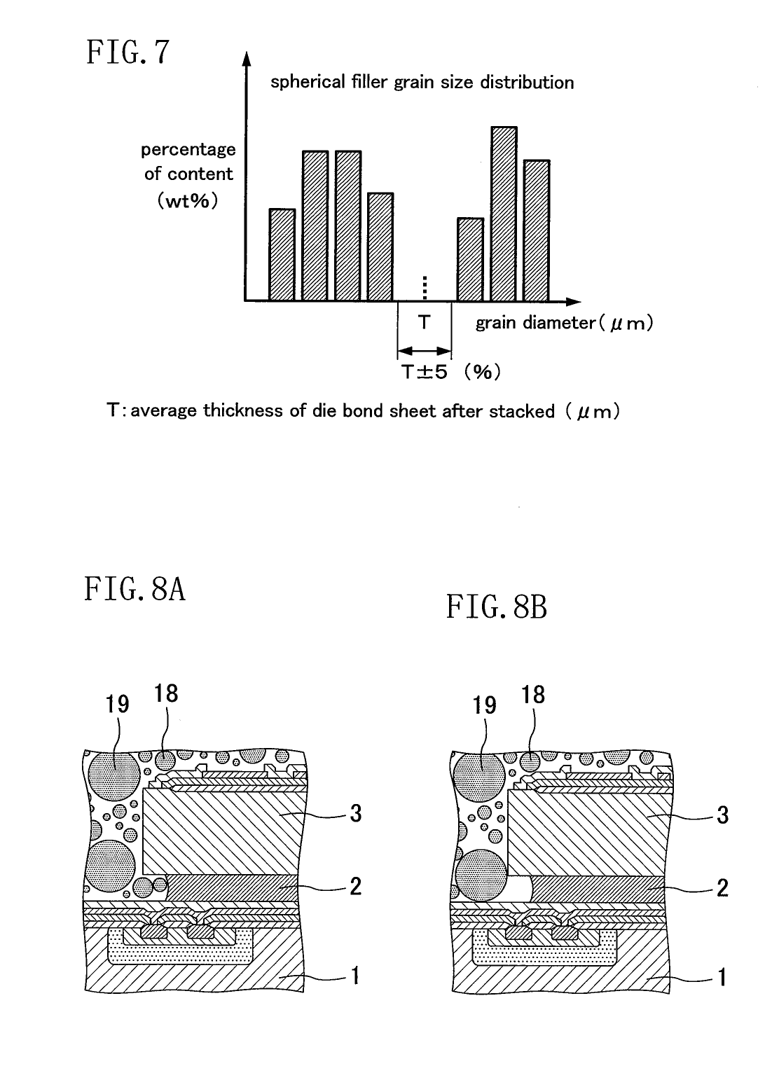

FIG. 7 shows the grain size distribution of the spherical fillers contained in the mold resin body 4 of the example semiconductor device of the present embodiment.

Referring to FIG. 3 and FIG. 7, in the example semiconductor device of the present embodiment, the thermosetting resin injected under pressure into the cavity 14 of the metal mold 13 is, for example, an epoxy resin which contains the first spherical fillers 18 (e.g., made of quartz) whose diameters are smaller than the average thickness (average thickness after molding) of the die bond sheet 2 interposed between the first semiconductor element 1 and the second semiconductor element 3 and the second spherical fillers 19 (e.g., made of quartz) whose diameters are larger than the average thickness of the die bond sheet 2 and which does not contain a spherical filler whose diameter is substantially equal to the average thickness of the die bond sheet 2.

Specifically, the thermosetting resin contains the first spherical fillers 18 that have different diameters smaller than the average thickness T of the die bond sheet 2 by more than 5% (i.e., smaller than 95% of average thickness T) and the second spherical fillers 19 that have different diameters larger than the average thickness T of the die bond sheet 2 by more than 5% (i.e., larger than 105% of average thickness T). Spherical fillers whose diameters differ from the average thickness T of the die bond sheet 2 by the differences in the range of ±5% are not contained in the thermosetting resin. Here, the average thickness of the die bond sheet 2 refers to the average thickness measured when the die bond sheet 2 is interposed between the first semiconductor element 1 and the second semiconductor element 3 as shown in FIG. 1.

The reasons why the spherical fillers having different diameters, the first smaller-diameter spherical fillers 18 and the second larger-diameter spherical fillers 19, are contained in the thermosetting resin are, for example, to approximate the thermal expansion coefficient of the mold resin body 4 containing the spherical fillers to those of the first semiconductor element 1 and the second semiconductor element 3, to secure the flowability of the thermosetting resin, and to secure the strength of the mold resin body 4.

The reasons to use the first spherical fillers 18 and second spherical fillers 19 having such diameters are now specifically described. FIG. 6 is a partially-enlarged, cross-sectional view of a comparative semiconductor device example. FIGS. 8A and 8B are enlarged cross-sectional views for illustrating the advantages of the example semiconductor device of the present embodiment.

Referring to FIG. 5, in the step of forming the mold resin body 4, the thermosetting resin is injected under pressure into the cavity 14 via the gate 16 of the metal mold 13 heated to 180° C. as previously described. In this step, part of the die bond sheet 2 near the gate 16 of the metal mold 13 sometimes retracts due to the pressure of injection of the resin so that a recess is formed between the first semiconductor element 1 and the second semiconductor element 3. If this case happens to the comparative example shown in FIG. 6 where the thermosetting resin contains spherical fillers 20 whose diameters are substantially equal to the average thickness of the die bond sheet 2, injection of the thermosetting resin under pressure into the cavity 14 causes the spherical fillers 20 to bite into the gap between the first semiconductor element 1 and the second semiconductor element 3. As a result, due to the pressure applied during molding with the thermosetting resin, the first semiconductor element 1 and the second semiconductor element 3, especially the wires 8 formed over the upper surface of the first semiconductor element 1, are damaged (crack 21 is caused).

In the case of the example semiconductor device of the present embodiment, on the other hand, the first spherical fillers 18 that have different diameters smaller than the average thickness T of the die bond sheet 2 by more than 5% may sometimes enter a recess formed by injection of the resin or a recess that exists between the first semiconductor element 1 and the second semiconductor element 3 even before injection of the resin as shown in FIG. 8A. However, the first spherical fillers 18 are not sandwiched between the first semiconductor element 1 and the second semiconductor element 3 so as to be in contact with both the first semiconductor element 1 and the second semiconductor element 3 (i.e., do not bite into the gap between the first semiconductor element 1 and the second semiconductor element 3). In other words, the first spherical fillers 18 are sufficiently smaller than the average thickness of the die bond sheet 2 so that they cannot be caught between the first semiconductor element 1 and the second semiconductor element 3. Thus, in the example semiconductor device, the first semiconductor element 1 and the second semiconductor element 3, especially the wires 8 formed over the upper surface of the first semiconductor element 1, are not damaged by the pressure applied during molding with the thermosetting resin.

Also, in the example semiconductor device of the present embodiment, the second spherical fillers 19 that have different diameters larger than the average thickness of the die bond sheet 2 by more than 5% may be contained in the thermosetting resin, in which a spherical filler whose diameter is substantially equal to the average thickness of the die bond sheet 2 is not contained. As shown in FIG. 8B, the diameters of the second spherical fillers 19 are sufficiently larger than the average thickness of the die bond sheet 2 so that the second spherical fillers 19 cannot enter the recess between the first semiconductor element 1 and the second semiconductor element 3. Therefore, there is no probability that the first semiconductor element 1 and the second semiconductor element 3 are damaged by the second spherical fillers 19. Due to the second larger-diameter spherical fillers 19 contained, the thermosetting resin exhibits improved flowability in the step of forming the mold resin body 4, so that occurrence of molding failure can be prevented.

Next, the other features of the example semiconductor device of the present embodiment are described.

In the example semiconductor device of the present embodiment, none of the first smaller-diameter spherical fillers 18 and the second larger-diameter spherical fillers 19 damages the first semiconductor element 1 or the second semiconductor element 3. Thus, the shape of the die bond sheet 2 is designed as described below such that the adhesion strength between the first semiconductor element 1 and the second semiconductor element 3 is improved.

Specifically, the horizontal profile size of the die bond sheet 2 is substantially equal to that of the second semiconductor element 3 while the size of the horizontal profile of the second semiconductor element 3 is smaller than that of the first semiconductor element 1 (in other words, the column-wise dimension and row-wise dimension of the horizontal profile of the second semiconductor element 3 are smaller than those of the first semiconductor element 1) such that the mounting stability of the second semiconductor element 3 on the first semiconductor element 1 is improved. Under such conditions, the horizontal profile of the die bond sheet 2 has such a shape that the perimeter is bowed inwardly and outwardly at irregular intervals relative to the horizontal profile of the second semiconductor element 3 as shown in FIG. 4. In other words, the horizontal profile of the die bond sheet 2 irregularly has recesses 2A and protrusions 2B.

When the horizontal profile of the die bond sheet 2 has such a shape that the recesses 2A and protrusions 2B irregularly occur, the perimeter of the horizontal profile of the die bond sheet 2 becomes longer, and accordingly, the adhesion strength of the die bond sheet 2 to the first semiconductor element 1 and to the second semiconductor element 3 increases. As a result, the mounting stability of the second semiconductor element 3 on the first semiconductor element 1 is further improved. Thus, in the example semiconductor device of the present embodiment, damages to the semiconductor elements and occurrences of molding failure are prevented, and hence, the reliability is greatly improved, as compared with the conventional semiconductor devices.

Although the above example semiconductor device of the present embodiment includes two semiconductor elements overmolded with resin, three or more semiconductor elements may be stacked and overmolded with resin.

The spherical fillers dispersed in the mold resin body 4 may be made of a material different from quartz according to the uses of the semiconductor device.

The adhesive layer for adherence between the first semiconductor element 1 and the second semiconductor element 3 is not limited to the die bond sheet but may be a liquid resin which does not contain fillers, for example.

—Other Specific Semiconductor Device Examples—

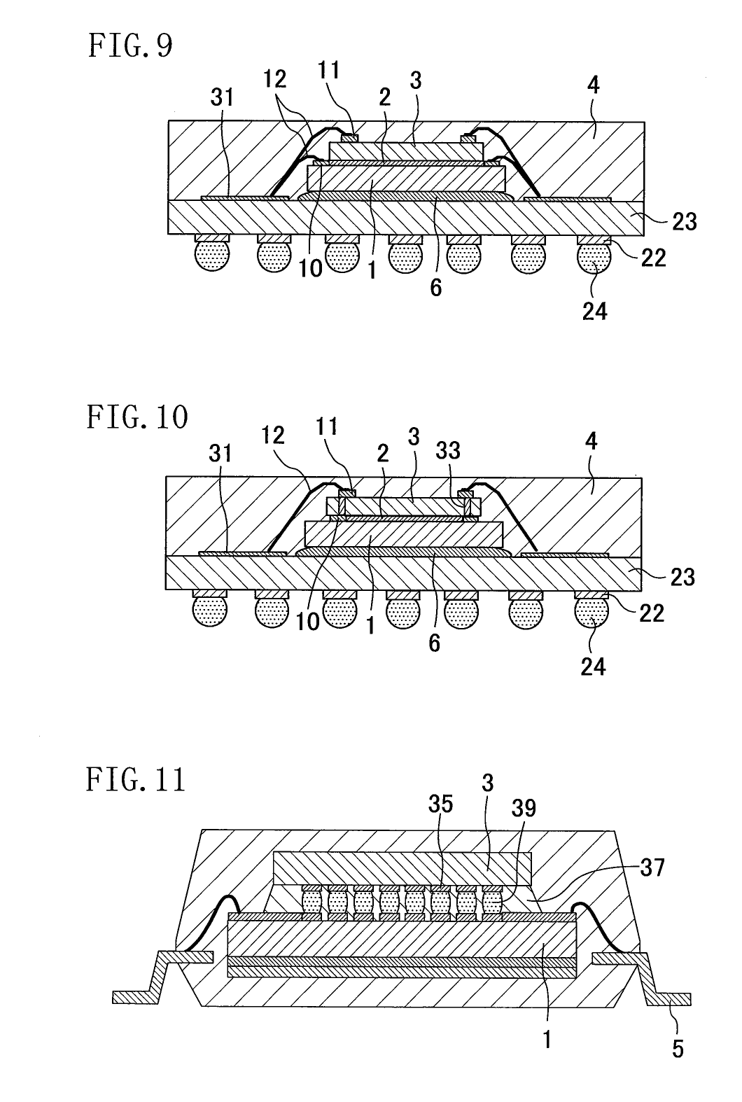

FIG. 9 is a cross-sectional view of a specific semiconductor device example which is different from the example semiconductor device of FIG. 1. As shown in FIG. 9, the structure described above is applicable to BGA (Ball Grid Array) type packages. Hereinafter, a structure of a semiconductor device is described for which a BGA-type package is employed. In this case, a BGA substrate serves as a supporter of the semiconductor device. Note that description of the same elements as those of the semiconductor device shown in FIG. 1 and FIG. 2 is simplified or omitted.

The specific semiconductor device example of FIG. 9 includes a substrate 23 (such as organic resin substrate or ceramic substrate) which has electrode pads 31 on the upper surface and external electrode terminals 22 on the lower surface, a first semiconductor element 1 adhesively mounted on the upper surface of the substrate 23 via the die bond agent 6, a second semiconductor element 3 adhesively mounted on the upper surface (circuit-formed surface) of the first semiconductor element 1 via the die bond sheet 2, metal wires 12 electrically coupling the electrodes 10 formed on the first semiconductor element 1 with the electrode pads 31 or electrically coupling the electrodes 11 formed on the second semiconductor element 3 with electrode pads 21, a mold resin body 4 overmolding the first semiconductor element 1, the second semiconductor element 3 and the metal wires 12, and external connection electrodes 24 connected to the external electrode terminals 22. The external connection electrodes 24 are formed by, for example, solder balls, by which electrical connection with a mother board, or the like, is established.

Although not shown in FIG. 9, as in the semiconductor device shown in FIG. 4, the first semiconductor element 1 has wires 8 on its upper surface, and the second semiconductor element 3 has wires 9 on its upper surface. The wires 8 and 9 are electrically coupled with external devices via the metal wires 12, the electrode pads, the external electrode terminals 22, etc.

Even with such a structure, damage to the first semiconductor element 1 and the second semiconductor element 3 is prevented, and occurrence of molding failure is also prevented, because the first smaller-diameter spherical fillers and the second larger-diameter spherical fillers are dispersed in the mold resin body 4 while a spherical filler whose diameter is substantially equal to the average thickness of the die bond sheet 2 is not contained in the mold resin body 4.

The above concept of the present invention is applicable to a semiconductor device having a different structure from those described above so long as the semiconductor device includes two or more semiconductor elements which are stacked and overmolded with resin.

In the semiconductor device example of FIG. 9, the first semiconductor element 1 and the second semiconductor element 3 have the wiring layers on their upper surfaces. However, in another example shown in FIG. 10 where the first semiconductor element 1 and the second semiconductor element 3 have through-hole electrodes 33 extending between their upper and lower surfaces, the first semiconductor element 1 and the second semiconductor element 3 may have the wiring layers on their lower surfaces.

In the examples described above, mounting of the first semiconductor element 1 and the second semiconductor element 3 is implemented by wire bonding. Alternatively, however, flip-chip mounting may be used for formation of the semiconductor device.

Alternatively, the wiring layer may be provided on the lower surface of the second semiconductor element as in an example which has a CoC (chip on chip) structure as shown in FIG. 11. In this case, connection bumps 35 provided on the lower surface of the second semiconductor element 3 are coupled with the wires formed on the first semiconductor element 1 via bumps 39. The adhesive layer 37 provided between the first semiconductor element 1 and the second semiconductor element 3 is, for example, formed by an overmold resin instead of the die bond sheet.

The concept of mixing fillers which have larger diameters than the average thickness of the adhesive layer and fillers which have smaller diameters than the average thickness of the adhesive layer in the adhesive layer is not limited to the examples described above and is applicable to any package in which two or more semiconductor chips are stacked. In this case, the advantages of the above examples can also be obtained.

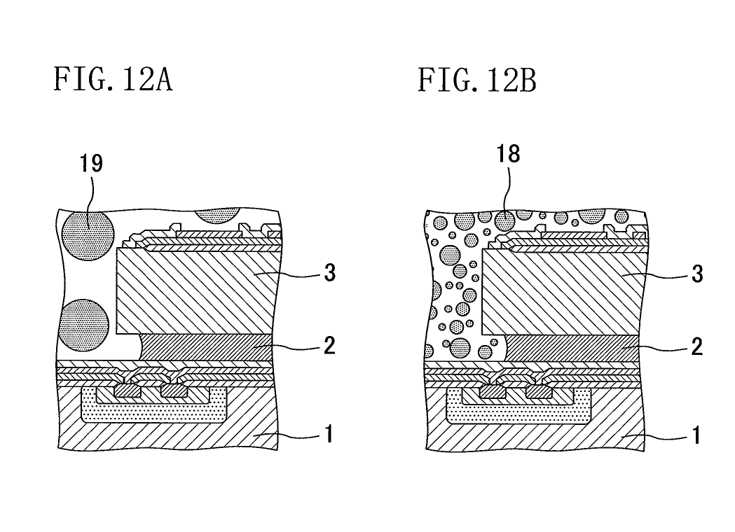

Even when only the second spherical fillers 19 that are greater than the average thickness T of the die bond sheet 2 by more than 5% are dispersed in the mold resin body 4 as shown in FIG. 12A, the spherical fillers are prevented from biting into the gap between the first semiconductor element 1 and the second semiconductor element 3 during molding. Thus, for example, the wires of the first semiconductor element 1 are effectively prevented from being damaged.

Alternatively, even when only the first spherical fillers 18 that are smaller than the average thickness T of the die bond sheet 2 by more than 5% are dispersed in the mold resin body 4 as shown in FIG. 12B, the spherical fillers are prevented from biting into the gap between the first semiconductor element 1 and the second semiconductor element 3 during molding. Thus, occurrence of damage can be prevented, and the reliability of the semiconductor device can be improved.

Thus, the resin-overmolded semiconductor devices described above as examples of the present invention are useful for improving the reliability of a variety of electronic devices.

The foregoing description illustrates and describes the present disclosure. Additionally, the disclosure shows and describes only the preferred embodiments of the disclosure, but, as mentioned above, it is to be understood that it is capable of changes or modifications within the scope of the concept as expressed herein, commensurate with the above teachings and/or skill or knowledge of the relevant art. The described hereinabove are further intended to explain best modes known of practicing the invention and to enable others skilled in the art to utilize the disclosure in such, or other embodiments and with the various modifications required by the particular applications or uses disclosed herein. Accordingly, the description is not intended to limit the invention to the form disclosed herein. Also it is intended that the appended claims be construed to include alternative embodiments.

What is claimed is:

1. A semiconductor device, comprising:
a first semiconductor element;
a second semiconductor element mounted on an upper surface of the first semiconductor element via an adhesive layer;
a mold resin body for overmolding the first semiconductor element and the second semiconductor element; and
a first spherical filler having a diameter smaller than an average thickness of the adhesive layer or a second spherical filler having a diameter larger than the average thickness of the adhesive layer, the first or second spherical filler being dispersed in the mold resin body.

2. The device of claim 1, wherein the mold resin body does not contain a spherical filler which has a diameter substantially equal to the average thickness of the adhesive layer.

3. The device of claim 1, wherein
the mold resin body contains the first spherical filler and the second spherical filler which are dispersed therein,
the diameter of the first spherical filler is smaller than the average thickness of the adhesive layer by more than 5%, and
the diameter of the second spherical filler is larger than the average thickness of the adhesive layer by more than 5%.

4. The device of claim 1, wherein
the adhesive layer is a die bond sheet,
a size of a horizontal profile of the second semiconductor element is smaller than that of the first semiconductor element,
the size of the horizontal profile of the adhesive layer is substantially equal to a size of a horizontal profile of part of the second semiconductor element which is placed on the first semiconductor element, and
the horizontal profile of the adhesive layer has such a shape that recesses and protrusions irregularly occur relative to the horizontal profile of the second semiconductor element.

5. The device of claim 1, wherein at least one of the upper surface of the first semiconductor element and the lower surface of the second semiconductor element has a wiring layer over which the adhesive layer is adhered.

6. A method for fabricating a semiconductor device, comprising:
(a) mounting a second semiconductor element on an upper surface of a first semiconductor element via an adhesive layer; and
(b) after (a), injecting a thermosetting resin into a metal mold holding the first semiconductor element and the second semiconductor element placed therein to form a mold resin body for overmolding the first and second semiconductor elements,
wherein the thermosetting resin used in (b) contains a first spherical filler which has a diameter smaller than an average thickness of the adhesive layer or a second spherical filler which has a diameter larger than the average thickness of the adhesive layer.

7. The method of claim 6, wherein
in (b), the thermosetting resin does not contain a spherical filler which has a diameter substantially equal to the average thickness of the adhesive layer.

8. The method of claim 6, wherein
the thermosetting resin used in (b) contains the first spherical filler and the second spherical filler,
the diameter of the first spherical filler is smaller than the average thickness of the adhesive layer by more than 5%, and
the diameter of the second spherical filler is larger than the average thickness of the adhesive layer by more than 5%.

9. The method of claim 6, wherein
the adhesive layer is a die bond sheet, and
(a) includes
(a1) before mounting the second semiconductor element on the first semiconductor element, adhering the die bond sheet onto a lower surface of a wafer that includes a plurality of units of the second semiconductor element, and
(a2) dividing the wafer into the units of the second semiconductor element having the die bond sheet on its lower surface.

10. The method of claim 6, wherein
in (a), the first semiconductor element has a wire formed on its upper surface, and the second semiconductor element has a wire formed on its upper or lower surface.
